(19) United States
(12) Patent Application Publication
(10) Pub. No.: US 2021/0259134 A1
(43) Pub. Date: Aug. 19, 2021

(54) SUBSTRATE COOLING USING HEAT PIPE VAPOR CHAMBER STIFFENER AND IHS LEGS

(71) Applicant: Intel Corporation, Santa Clara, CA (US)

(72) Inventors: Aastha UPPAL, Chandler, AZ (US); Divya MANI, Chandler, AZ (US); Je-Young CHANG, Tempe, AZ (US)

(21) Appl. No.: 16/794,747

(22) Filed: Feb. 19, 2020

(51) Int. Cl. H05K 7/20

(52) U.S. Cl. CPC H05K 7/20336; H05K 7/2039

(57) ABSTRACT

Embodiments disclosed herein include an integrated heat spreader (IHS). In an embodiment, the IHS comprises a main body, where the main body comprises a first surface and a second surface opposite from the second surface. In an embodiment, the IHS further and a support extending from the first surface of the main body. In an embodiment, the support comprises a shell, and a layer over an interior surface of the shell.

### TECHNICAL FIELD

Embodiments of the present disclosure relate to semiconductor devices, and more particularly to cooling solutions for package substrates that include heat pipes or vapor chambers that are used as a stiffener or legs for an integrated heat spreader (IHS).

### BACKGROUND

A key parameter of electronic packaging is thermal management. One aspect of thermal management in electronic packaging is the ability to remove heat from the package substrate. Removal of heat from the package substrate is particularly critical when components are embedded in the package substrate. For example, high power electronic components like high current carrying voltage regulators, may be embedded in some package substrates. These high power components within the package may result in localized heat generation in the substrate due to joule heating and component heat generation. Without a way to efficiently remove the heat from the package substrate, package burn or thermal run-away may occur. As such, the electronic package may be damaged or completely fail.

Removal of excess thermal energy from the package substrate is particularly difficult due to the high thermal resistance of the package substrate materials. Furthermore, currently used thermal solutions are optimized for removal of thermal energy from the die (or dies) coupled to the package substrate. Additional thermal solutions targeted at removal of the thermal energy from the package substrate add cost and may increase the form factor of the electronic package.

### BRIEF DESCRIPTION OF THE DRAWINGS

FIG. 1A is a perspective view illustration of a support for an integrated heat spreader (IHS), in accordance with an embodiment.

FIG. 1B is a cross-sectional illustration of the support in FIG. 1A, in accordance with an embodiment.

FIG. 2A is a perspective view illustration of an IHS with a main body and a support, in accordance with an embodiment.

FIG. 2B is a cross-sectional illustration of the IHS in FIG. 2A, in accordance with an embodiment.

FIG. 3 is a cross-sectional illustration of an IHS with the main body and the support coupled together as a monolithic structure, in accordance with an additional embodiment.

FIG. 4A is a cross-sectional illustration of an electronic package that includes an IHS with a support for removing thermal energy from the package substrate, in accordance with an embodiment.

FIG. 4B is a plan view illustration of the electronic package in FIG. 4A where the support is a ring, in accordance with an embodiment.

FIG. 4C is a plan view illustration of the electronic package in FIG. 4A where the support comprises a plurality of posts, in accordance with an embodiment.

FIG. 5A is a cross-sectional illustration of an electronic package that includes an IHS with a support for removing thermal energy from the package substrate, and where the package substrate is coreless, in accordance with an embodiment.

FIG. 5B is a cross-sectional illustration of an electronic package with stacked dies and an IHS with a support for removing thermal energy from the package substrate, in accordance with an embodiment.

FIG. 6A is a cross-sectional illustration of an electronic package that is a bare die package and includes a stiffener that provides thermal regulation of the package substrate, in accordance with an embodiment.

FIG. 6B is a cross-sectional illustration of the electronic package in FIG. 6A with a thermal solution coupled to the stiffener, in accordance with an embodiment.

FIG. 7 is a cross-sectional illustration of an electronic system with an IHS that comprises a support for thermal management of the package substrate, in accordance with an embodiment.

FIG. 8 is a schematic of a computing device built in accordance with an embodiment.

### EMBODIMENTS OF THE PRESENT DISCLOSURE

Described herein are electronic packages with cooling solutions for package substrates that include heat pipes or vapor chambers that are used as a stiffener or legs for an integrated heat spreader (IHS), in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, it is becoming more critical to remove thermal energy from the package substrate as more components are embedded in the package substrate of electronic packages. However, simply adding additional thermal solutions to the electronic packages may be too costly or increase the form factor. As such, embodiments disclosed herein provide a thermal solution that is integrated into existing thermal solutions or mechanical features.

For example, in one embodiment, the IHS is modified so that the supports (e.g., legs, etc.) of the IHS have a high thermal conductivity and are thermally coupled to the package substrate. In some embodiments, the supports may include a heat pipe or a vapor chamber. Accordingly, thermal energy from the package substrate may be efficiently propagated to the main body of the IHS that is in contact with a heat sink, fins, or the like.

Additional embodiments disclosed herein may be implemented in bare die architectures (i.e., where there is no IHS). In such embodiments, a stiffener of the electronic package may be modified to provide a heat pipe or a vapor chamber. The stiffener is thermally coupled between a surface of the package substrate and the thermal solution (e.g., heat sink, fins, or the like). Since a stiffener may already be necessary for the electronic package, there is no increase in the form factor attributable to the cooling of the package substrate.

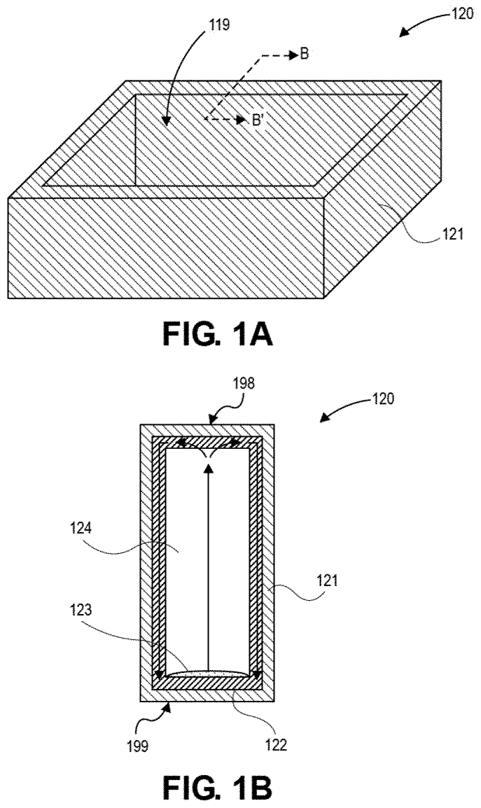

Referring now to FIG. 1A, a perspective view illustration of a support 120 is shown, in accordance with an embodiment. In an embodiment, the support 120 may be for supporting a main body (not shown) of an IHS, or the support 120 may be a stiffener. More detailed explanations of the IHS embodiment and the stiffener embodiment will be described in greater detail below. In an embodiment, the support 120 may be ring shaped. For example, the support 120 in FIG. 1A is substantially square shaped. The support 120 may comprise a shell 121 that forms a ring around an opening 119. In an embodiment, the shell 121 may be any suitable material with a relatively high thermal conductivity. For example, the shell 121 may be a metallic material, such as stainless steel, copper, or the like.

Referring now to FIG. 1B, a cross-sectional illustration of the support 120 along line B-B′ in FIG. 1A is shown, in accordance with an embodiment. As shown, the shell 121 defines a void 124 in the interior of the support 120. In an embodiment, a layer 122 may line portions of an interior surface of the shell 121. For example, the layer 122 may cover substantially the entire interior surface of the shell 121. The layer 122 may be a wicking layer. That is, the layer 122 may be designed in order to serve as a wick for a phase change material 123 that is within the shell 121. In an embodiment, the layer 122 may use any suitable wicking layer constructions used in heat pipes or vapor chambers. For example, the layer 122 may be a sintered layer or a screen layer. In other embodiments, the layer 122 may be a monolithic part of the shell 121. That is, the layer 122 may be a surface modification of the interior surface of the shell 121. For example, the layer 122 may comprise grooves or other features patterned into the interior surface of the shell 121. A bottom surface 199 of the shell 121 may be thermally coupled to the component that is to be temperature controlled (e.g., a package substrate), and a top surface 198 of the shell 121 may be thermally coupled to a heat sink or the like in order to remove thermal energy from the support 120.

The phase change material 123 provides a mechanism for heat transfer within the support 120 between the bottom surface 199 and the top surface 198. During operation, the heat input into the bottom surface 199 vaporizes phase change material 123 within the layer 122. The vapor flows throughout the chamber (as indicated by the vertical arrow in the void 124), creating an isothermal heat spreader. The vapor condenses on the layer 122 along the cooled top surface 198, and capillary forces in the wick layer 122 return the condensate of the phase change material 123 to the bottom surface 199 of the shell 121. In an embodiment, the phase change material 123 may be any material composition that is capable of undergoing a phase change from a liquid to gas at standard operating temperatures of an electronic package. In a particular embodiment, the phase change material 123 may comprise water. In an embodiment, the void 124 is hermetically sealed. That is, the shell 121 may form a hermetic seal in order to prevent the phase change material 123 from exiting the void 124.

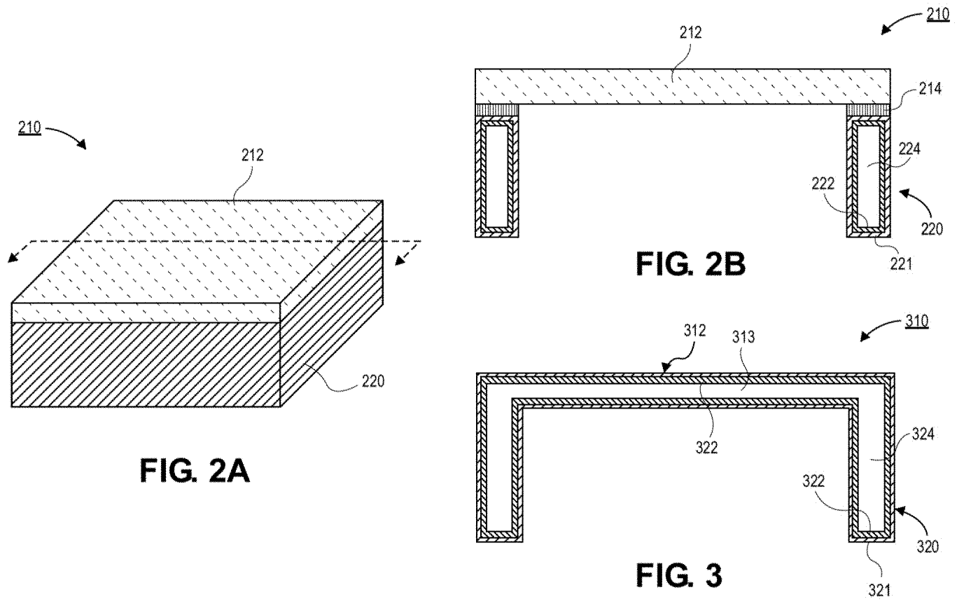

Referring now to FIG. 2A, a perspective view illustrations of an IHS 210 is shown, in accordance with an embodiment. In an embodiment, the IHS 210 may comprise a main body 212 and a support 220. The support 220 may be substantially similar to the support 120 described above. In an embodiment, the main body 212 is thermally coupled to the support 220. As such, the thermal energy transferred to the top surface of the support 220 may be removed by the main body 212. Embodiments may include a support 220 that surrounds a perimeter of the main body 212. That is, the IHS 210 may have a single support 220 that is attached to the main body 212. In other embodiments, a plurality of supports 220 may be attached to the main body 212 (as will be described in greater detail below). In an embodiment, the main body 212 may be any suitable high thermal conductivity material suitable for use in IHS architectures. For example, the main body 212 may be copper, stainless steel, or the like. In some embodiments, the main body 212 may include a core material and a plated material surrounding the core. For example, a nickel plating may surround a copper core in some embodiments.

Referring now to 2B, a cross-sectional illustration of the IHS 210 along line B-B′ in FIG. 2A is shown, in accordance with an embodiment. As shown, the support 220 may comprise a shell 221 and a layer 222 lining an interior surface of the shell 221. The shell 221 may confine a void 224. The shell 221 and the layer 222 may be similar to the shell 121 and layer 122 described above. In an embodiment, the shell 221 may be attached to the main body 212 of the IHS 210. For example, a solder 214 or other thermal adhesive may be used to secure the main body 212 to the shell 221.

In FIG. 2B, the IHS 210 is shown as having a support 220 and a main body 212 that are discrete components. However, it is to be appreciated that in some embodiments, the main body 212 and the support 220 may be formed as a single component. An example of such an embodiment is shown in FIG. 3.

FIG. 3 is a cross-sectional illustration of an IHS 310, in accordance with an additional embodiment. As shown, the support 320 and the main body 312 are part of a single monolithic structure. That is, the shell 321 may be a continuous structure that is used for the main body 312 and the support 320. Particularly, a void 324 of the support 320 may be fluidically coupled to a void 313 of the main body 312. In an embodiment, a layer 322 (e.g., a wicking layer) may cover interior surfaces of the shell 321 in the support 320 and the main body 312. In an embodiment, the layer 322 is a continuous layer and covers the entire interior surface of the shell 321. In other embodiments, the layer 322 covers portions of the interior surface of the shell 321.

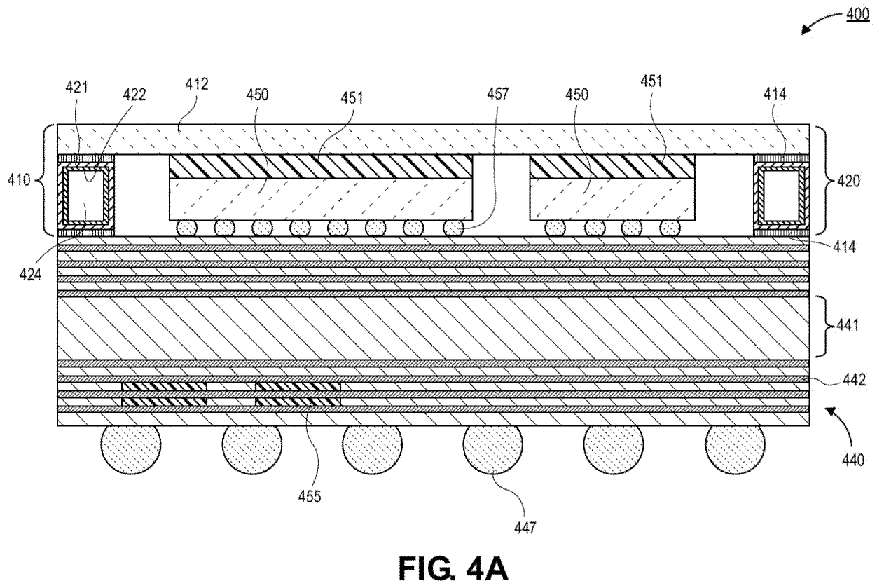

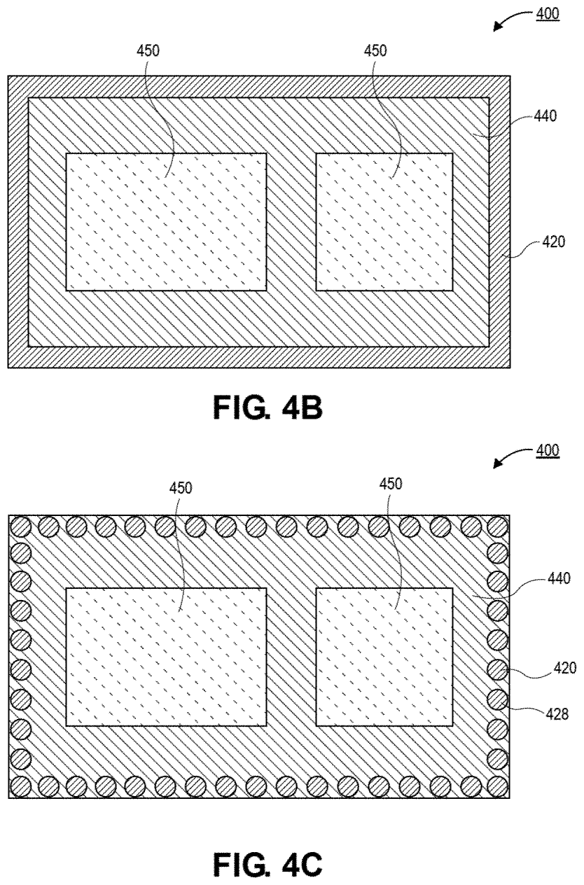

Referring now to FIG. 4A, a cross-sectional illustration of an electronic package 400 is shown, in accordance with an embodiment. The electronic package 400 may comprise a package substrate 440, one or more dies 450, and an IHS 410. In the illustrated embodiment, a pair of dies 450 are illustrated. The dies 450 may be coupled to the package substrate 440 by interconnects 457. The interconnects 457 may be first level interconnects. For example, the interconnects 457 may comprise solder balls, copper pillars, or the like.

In an embodiment, different types of dies 450 may be attached to the package substrate 440. For example, a first die 450 (e.g., the left die 450) may be a processor and a second die 450 (e.g., the right die 450) may be a memory die. However, it is to be appreciated that any type (or types) of dies 450 may be attached to the package substrate 440. As used herein, one or more dies 450 may be referred to as a die module. That is, a single die 450 may be referred to a die module or two or more dies may be referred to as a die module.

In an embodiment, the package substrate 440 may be an organic package substrate. The package substrate may include laminated insulating layers and conductive features 442. The conductive features shown in FIG. 4A are traces, but it is to be appreciated that the conductive features 442 may also comprise vias to connect traces in different layers, pads to connect to the interconnects 457, or the like. In an embodiment, the package substrate 440 may be a cored substrate. That is, the package substrate 440 may comprise a core 441. In such an embodiment, laminated layers may be disposed above and below the core 441. Through core vias (not shown) may make electrical connections from one side of the core 441 to the other side of the core 441. For example, connections may be made through the package substrate 440 from the interconnects 457 to the interconnects 447.

In an embodiment, the package substrate 440 may comprise one or more embedded components 455. The embedded components 455 in FIG. 4A are shown as being located on the opposite side of the core 441 from the dies 450. In other embodiments, the embedded components 455 may be between the core 441 and the dies 450, or above and below the core 441. In some embodiments, the embedded components 455 may be a significant source of thermal energy. For example, components 455 that carry high currents may result in significant joule heating. In a particular embodiment, the embedded components 455 may comprise voltage regulators like air core inductors (ACIs). These voltage regulators are particularly susceptible to joule heating due to the high amounts of current passed through these components 455. As such, there may be significant heating of the package substrate 440 during operation of the electronic package 400. In other embodiments, the components 455 may include resistors, capacitors, active dies, passive dies, inductors, or any other component needed for the operation of the electronic package 400.

In an embodiment, the thermal energy from the package substrate 440 may be removed in part by the IHS 410. Particularly, the support 420 of the IHS 410 may be thermally coupled to the package substrate 440. For example, a bottom surface of the shell 421 may be attached to the package substrate 440 by a solder 414 or other thermal adhesive. In order to provide efficient thermal dissipation through the support 420 to the main body 412 of the IHS 410, the support 420 may comprise a heat pipe or a vapor chamber. For example, the support 420 may comprise a shell 421 with an internal void 424. The interior surface of the shell 421 may be lined with a wicking layer 422. A phase change material (not shown) similar to the phase change material 123 described above may be within the void 424 to implement the heat transfer from the package substrate 440 to the main body 412 of the IHS 410.

In an embodiment, the main body 412 of the IHS 410 may be thermally coupled to the top surface of the shell 421 of the support 420 by a solder 414 or other thermal adhesive. The main body 412 may also be thermally coupled to the one or more dies 450. For example, a thermal interface material (TIM) 451 or the like may thermally couple the backside surfaces of the dies 450 to the main body 412 of the IHS 410. In the illustrated embodiment, the main body 412 and the support 420 are shown as discrete components, similar to the embodiment shown in FIG. 2B. However, it is to be appreciated that embodiments may also include an IHS 410 that has a construction similar to the IHS 310 in FIG. 3 with a main body 412 and support 420 with voids 424 that are fluidically coupled together.

Referring now to FIG. 4B, a plan view illustration of the electronic package 400 is shown, in accordance with an embodiment. In the illustrated embodiment, the main body 412 of the IHS 410 is removed in order to not obscure the underlying components. As shown, the support 420 may be ring shaped. That is, the support 420 may encircle a perimeter of the one or more dies 450. In an embodiment, the support 420 may be proximate to an edge of the package substrate 440. However, other embodiments may have the support 420 offset from one or more of the edges of the package substrate.

Referring now to FIG. 4C, a plan view illustration of the electronic package 400 is shown, in accordance with an additional embodiment. As shown, the support 420 may comprise a plurality of posts 428. The plurality of posts 428 may be secured to the main body 412 (not shown) of the IHS 410. In an embodiment, individual ones of the posts 428 may each comprise a shell 421, a layer 422 lining an interior surface of the shell 421 and a void 424. That is, the heat transfer may be implemented across a plurality of discreet voids 424, as opposed to a single continuous void 424 that wraps around in a ring, as shown in FIG. 4B.

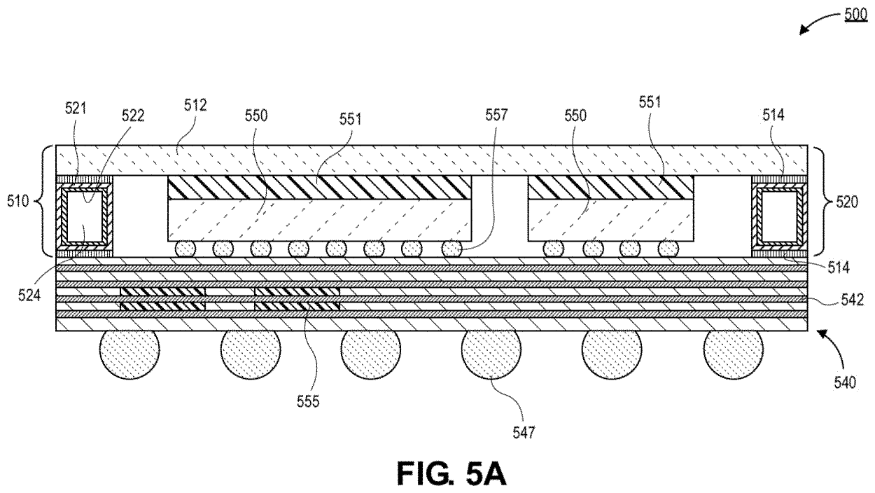

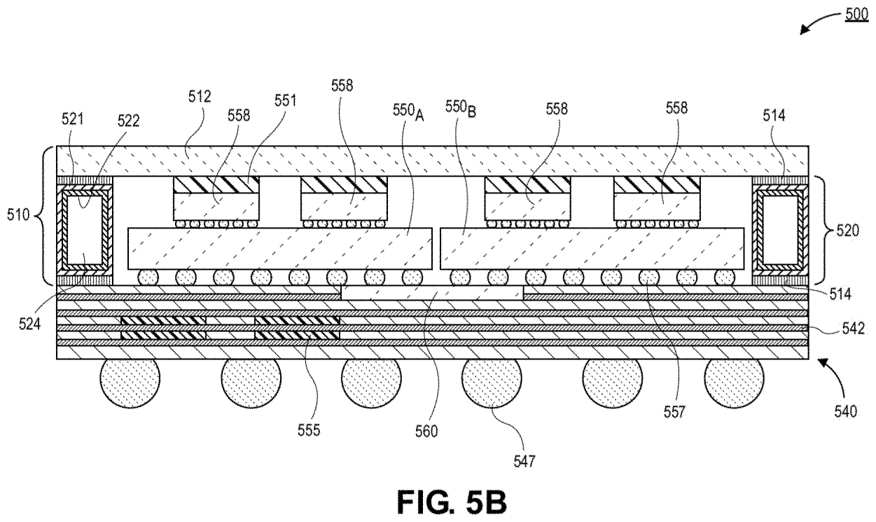

Referring now to FIG. 5A, a cross-sectional illustration of an electronic package 500 is shown, in accordance with an additional embodiment. In an embodiment, the electronic package 500 may comprise a package substrate 540, one or more dies 550, and an IHS 510. In an embodiment, the one or more dies 550 may be attached to the package substrate by interconnects 557. The one or more dies 550 may be similar to the one or more dies 450 described above. In an embodiment, the IHS 510 may be similar to the IHS 410 described above. That is, the IHS 510 may comprise a support 520 and a main body 512. The support 520 may comprise a shell 521, a layer 522 over an interior surface of the shell 521 and a void 524. The support 520 may be thermally coupled to the main body 512 by a solder 514 or the like. In an embodiment, the dies 550 may be thermally coupled to the main body 512 by a TIM 551.

In an embodiment, the package substrate 540 in FIG. 5A may differ from the package substrate 440 in that the package substrate 540 is a coreless substrate. For example, the package substrate 540 may comprise laminated organic layers and conductive features 542 between laminated layers. The conductive features 542 may provide an electrical connection between interconnects 557 and interconnects 547. In an embodiment, one or more components 555 may be embedded in the package substrate 540. For example, the components 555 may include voltage regulators like ACIs, resistors, capacitors, active dies, passive dies, inductors, or any other component needed for the operation of the electronic package 500.

Referring now to FIG. 5B, a cross-sectional illustration of an electronic package 500 is shown, in accordance with an additional embodiment. In an embodiment, the electronic package 500 in FIG. 5B is similar to the electronic package 500 in FIG. 5A, with the exception that dies 550 and 558 are stacked. For example, individual ones of the dies 550A and 550E may comprise stacked dies 558 on their backside surfaces. In the illustrated embodiments, a pair of dies 558 are positioned over a backside surface of each of the dies 550A and 550B. In some embodiments, a group of stacked dies (e.g., a first die 550A and the stacked dies 558 over the first die 550A) may be referred to as a die module. In an embodiment, the backside surfaces of the dies 558 are thermally coupled to the main body 512 of the IHS 510 by a TIM 551.

In an embodiment, the electronic package 500 may also comprise an embedded multi-die interconnect bridge (EMIB) 560. In such embodiments, the EMIB 560 is embedded in the package substrate 540 and provides electrical coupling between the dies 550A and 550B. The dies 550A and 550E may be electrically coupled to the EMIB 560 by interconnects 557. Accordingly, the first die 550A may be communicatively coupled to the second die 550B.

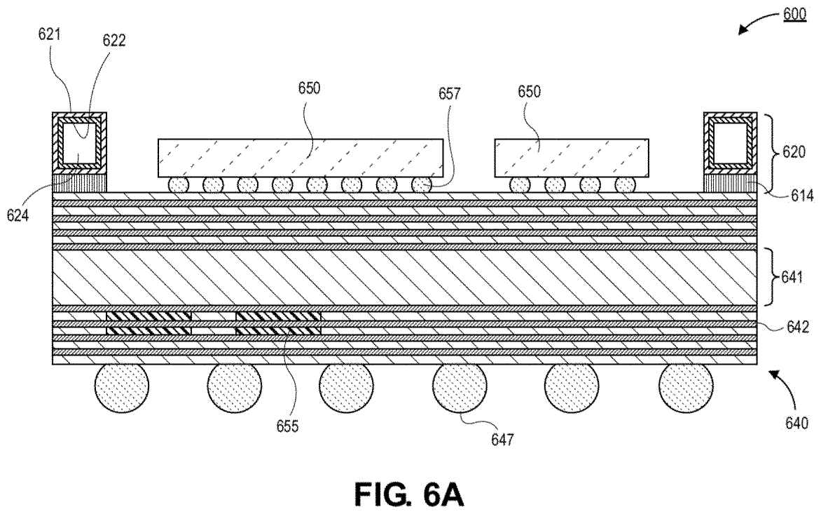

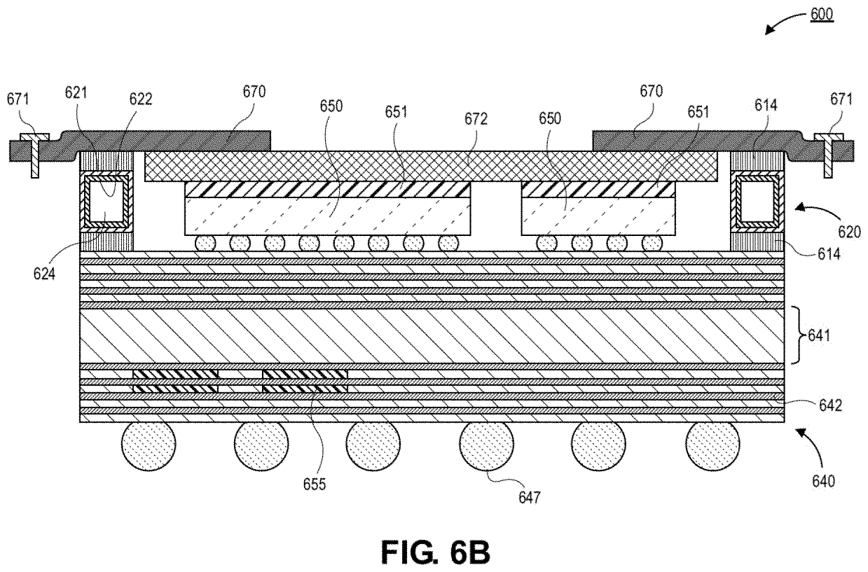

Referring now to FIG. 6A, a cross-sectional illustration of an electronic package 600 with a bare die architecture is shown, in accordance with an embodiment. In an embodiment, the electronic package 600 may comprise a package substrate 640 and one or more dies 650. In an embodiment, the package substrate 640 may comprise a core 641. In other embodiments, the package substrate 640 is coreless. In an embodiment, conductive features 642 (e.g., traces, vias, pads, etc.) may be embedded and/or on the package substrate 640. The conductive features 642 may provide an electrical path through the package substrate 640 from interconnects 657 to interconnects 647.

In some embodiments, the package substrate 640 may comprise one or more embedded components 655. The components 655 may include resistors, capacitors, active dies, passive dies, inductors, or any other component needed for the operation of the electronic package 600. In a particular embodiment, the components 655 may comprise ACIs. During operation, the embedded components 655 may heat the package substrate 640. Accordingly, embodiments disclosed herein may include a thermal solution for removing heat from the package substrate 640.

In an embodiment, the electronic package 600 may also comprise a support 620. Structurally, the support 620 may function as a stiffener. That is, the support 620 may increase the stiffness of the electronic package 600 and reduce warpage of the electronic package 600. In an embodiment, the support 620 may be a ring-shaped support. For example, the support 620 may have a shape similar to the shape of the support 420 illustrated in FIG. 4B.

In an embodiment, the support 620 may also function as a thermal solution. For example, the support 620 may comprise a heat pipe or a vapor chamber. Particularly, in some embodiments, the support 620 may comprise a shell 621. A layer 622 may be disposed over an interior surface of the shell 621. The layer 622 may be substantially similar to the layer 122 in FIG. 1B. That is, the layer 622 may be a wicking layer. In an embodiment, the layer 622 may be a sintered layer or a screen layer. In other embodiments, the layer 622 may be a monolithic part of the shell 621. That is, the layer 622 may be a surface modification of the interior surface of the shell 621. For example, the layer 622 may comprise grooves or other features patterned into the interior surface of the shell 621. In an embodiment, a phase change material (not shown) may be disposed in the shell 621 in order to effectuate heat transfer away from the package substrate. For example, the phase change material may comprise water or the like. In an embodiment, a void 624 within the shell 621 may be hermetically sealed.

In an embodiment, the support 620 may be thermally coupled to the package substrate 640. For example, the support 620 may be attached to the package substrate 640 by a solder 614 or other suitable thermal adhesive. Accordingly, heat from the package substrate 640 may be propagated to the bottom surface of the support 620.

Referring now to FIG. 6B, a cross-sectional illustration of a bare die electronic package 600 with a thermal solution attached to the support 620 is shown, in accordance with an embodiment. In an embodiment, the thermal solution may comprise a frame 670. The frame 670 may be thermally coupled to the support 620. For example, a solder 614 or other thermal adhesive may secure the frame 670 to the support 620. In an embodiment, the frame 670 may be secured to a thermal block 672, such as a heat sink. In an embodiment, the thermal block 672 may also be thermally coupled to the dies 650 by a TIM 651. In an embodiment, thermal energy from the package substrate 640 may propagate through the support 620, into the frame 670, and to the thermal block 672. The frame 670 may comprise fasteners 671 (e.g., screws, pins, clamps, or the like) used to secure the frame 670 to the package substrate 640. In an embodiment, the fasteners 671 may be secured to a board (not shown).

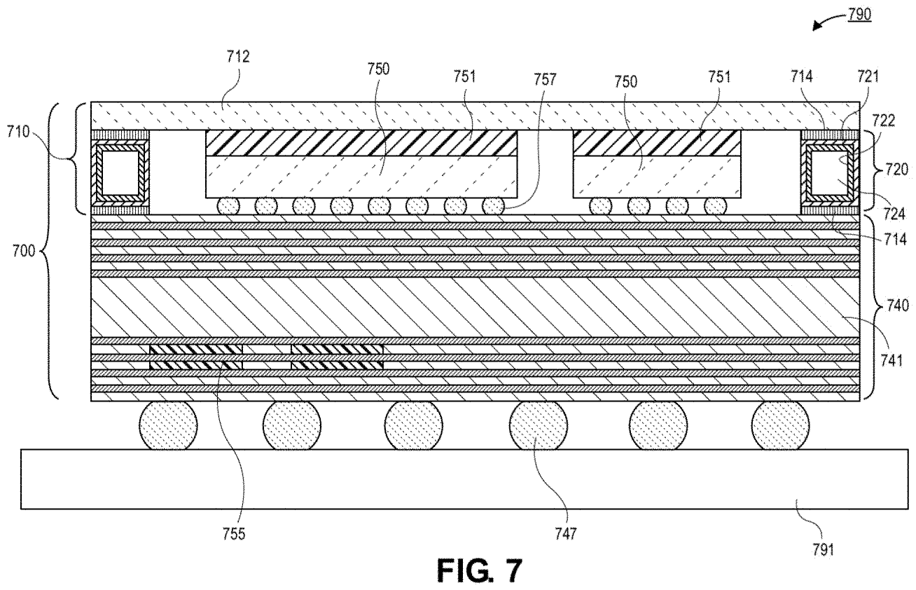

Referring now to FIG. 7, a cross-sectional illustration of an electronic system 790 is shown, in accordance with an embodiment. In an embodiment, the electronic system 790 may comprise an electronic package 700 that is attached to a board 791. The electronic package 700 may be attached to the board 791 by interconnects 747. In the illustrated embodiment, the interconnects 747 are shown as being solder balls. However, it is to be appreciated that the interconnects 747 may be any suitable interconnects, such as sockets, wire bonds, or the like.

In an embodiment, the electronic package 700 may comprise a package substrate 740 and one or more dies 750. In the illustrated embodiment, the electronic package 700 comprises an IHS 710. However, in other embodiments, the electronic package 700 may be a bare die package, similar to the embodiment described with respect to FIG. 6B. In the illustrated embodiment, a pair of dies 750 that are laterally adjacent to each other is shown. However, it is to be appreciated that a plurality of dies 750 and/or stacked die architectures (similar to the embodiment described with respect to FIG. 5B) may be included in the electronic system 790. The dies 750 may be thermally coupled to the IHS 710 by a TIM 751. In an embodiment, the dies 750 may be attached to the package substrate 740 by interconnects 757.

In an embodiment, the package substrate 740 may comprise a core 741. In other embodiments, the package substrate 740 may be coreless. Embodiments may also include a package substrate 740 that comprises one or more embedded components 755. In an embodiment, the embedded components 755 include resistors, capacitors, active dies, passive dies, inductors, or any other component needed for the operation of the electronic system 790. In a particular embodiment, the embedded components 755 may comprise one or more voltage regulators.

In an embodiment, the IHS 710 may be similar to any of the IHS embodiments described herein. For example, the IHS 710 may comprise a main body 712 and a support 720. In an embodiment, the support 720 is thermally coupled to the package substrate 740 and the main body 712 by a solder 714 or other thermal adhesive. In an embodiment, the support 720 may comprise a shell 721 with a layer 722 lining an interior surface of the shell 721. For example, the layer 722 may be a wicking layer, such as those described above. A phase change material (not shown) may be within the void 724 defined by the shell 721.

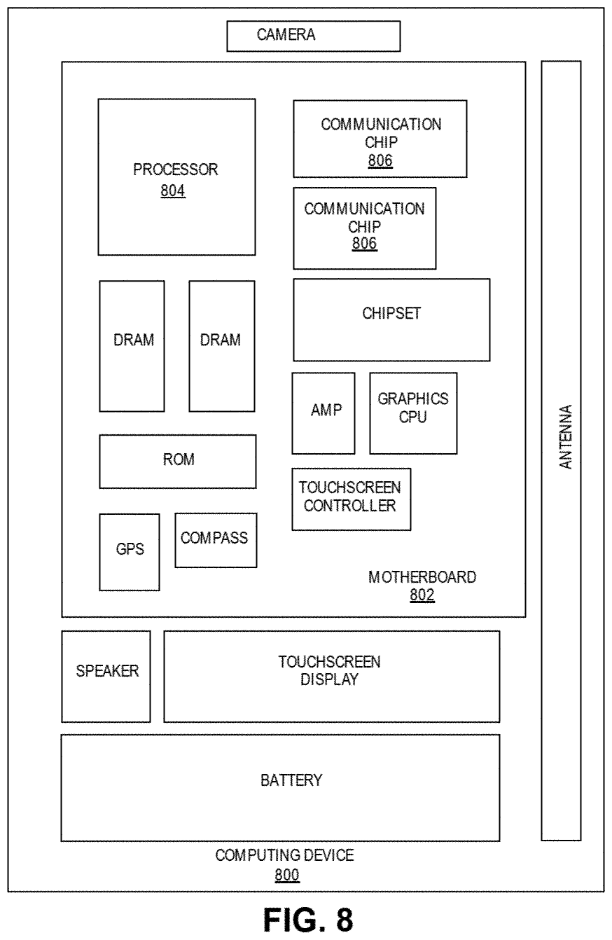

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an electronic package that comprises a support that is a heat pipe or a vapor chamber, with the support thermally coupled to a package substrate, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip 806 may be part of an electronic package that comprises a support that is a heat pipe or a vapor chamber, with the support thermally coupled to a package substrate, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an integrated heat spreader (IHS), comprising: a main body, wherein the main body comprises a first surface and a second surface opposite from the second surface; and a support extending from the first surface of the main body, wherein the support comprises: a shell; and a layer over an interior surface of the shell.

Example 2: the IHS of Example 1, further comprising: a phase change material within the shell.

Example 3: the IHS of Example 1 or Example 2, wherein the layer is a wicking layer.

Example 4: the IHS of Example 3, wherein the wicking layer is a sintered layer, a screen layer, or a grooved layer.

Example 5: the IHS of Examples 1-4, wherein the shell is hermetically sealed.

Example 6: the IHS of Examples 1-5, wherein the support is a ring.

Example 7: the IHS of Example 6, wherein the ring is proximate to an edge of the main body.

Example 8: the IHS of Examples 1-7, wherein the support comprises a plurality of posts, wherein individual ones of the plurality of posts comprise the shell.

Example 9: the IHS of Examples 1-8, wherein the support is attached to the main body by a solder.

Example 10: the IHS of Examples 1-9, wherein the main body comprises a second shell, and wherein the shell of the support is fluidically coupled to the second shell.

Example 11: the IHS of Example 10, wherein the layer lines an interior surface of the second shell.

Example 12: the IHS of Examples 1-11, wherein the support is a heat pipe or a vapor chamber.

Example 13: an electronic package, comprising: a package substrate; a die module on the package substrate; and a support attached to the package substrate, wherein the support surrounds a perimeter of the die module, and wherein the support comprises: a shell, wherein the shell is hermetically sealed; a layer over an interior surface of the shell; and a phase change material in the shell.

Example 14: the electronic package of Example 13, wherein the support is attached to the package substrate by a solder.

Example 15: the electronic package of Example 12 or Example 13, further comprising: a lid attached to the support, wherein the lid is thermally coupled to the die module by a thermal interface material (TIM).

Example 16: the electronic package of Example 15, wherein the lid is attached to the support by a second solder.

Example 17: the electronic package of Example 15, wherein the lid comprises a second shell and a second layer lines the second shell, and wherein an interior volume of the second shell is fluidically coupled to an interior volume of the shell.

Example 18: the electronic package of Examples 13-17, wherein the support is thermally coupled to a thermal block.

Example 19: the electronic package of Examples 13-18, wherein the support comprises a plurality of posts, wherein individual ones of the plurality of posts comprise the shell.

Example 20: the electronic package of Examples 13-19, wherein the die module comprises: a first die; and a second die on the first die.

Example 21: the electronic package of Examples 13-20, further comprising: a component embedded in the package substrate.

Example 22: the electronic package of Example 21, wherein the component is a fully integrated voltage regulator.

Example 23: an electronic system, comprising: a board; a package substrate coupled to the board; a die module coupled to the package substrate; and a support around a perimeter of the die module, wherein the support comprises a heat pipe or a vapor chamber.

Example 24: the electronic system of Example 23, wherein the support is part of an integrated heat spreader (IHS).

Example 25: the electronic system of Example 23 or Example 24, wherein the support comprises: a shell; and a layer over an interior surface of the shell.

What is claimed is:

1. An integrated heat spreader (IHS), comprising:
a main body, wherein the main body comprises a first surface and a second surface opposite from the second surface; and
a support extending from the first surface of the main body, wherein the support comprises:
a shell; and
a layer over an interior surface of the shell.

2. The IHS of claim 1, further comprising:
a phase change material within the shell.

3. The IHS of claim 1, wherein the layer is a wicking layer.

4. The IHS of claim 3, wherein the wicking layer is a sintered layer, a screen layer, or a grooved layer.

5. The IHS of claim 1, wherein the shell is hermetically sealed.

6. The IHS of claim 1, wherein the support is a ring.

7. The IHS of claim 6, wherein the ring is proximate to an edge of the main body.

8. The IHS of claim 1, wherein the support comprises a plurality of posts, wherein individual ones of the plurality of posts comprise the shell.

9. The IHS of claim 1, wherein the support is attached to the main body by a solder.

10. The IHS of claim 1, wherein the main body comprises a second shell, and wherein the shell of the support is fluidically coupled to the second shell.

11. The IHS of claim 10, wherein the layer lines an interior surface of the second shell.

12. The IHS of claim 1, wherein the support is a heat pipe or a vapor chamber.

13. An electronic package, comprising:
a package substrate;
a die module on the package substrate; and
a support attached to the package substrate, wherein the support surrounds a perimeter of the die module, and wherein the support comprises:
a shell, wherein the shell is hermetically sealed;
a layer over an interior surface of the shell; and
a phase change material in the shell.

14. The electronic package of claim 13, wherein the support is attached to the package substrate by a solder.

15. The electronic package of claim 13, further comprising:
a lid attached to the support, wherein the lid is thermally coupled to the die module by a thermal interface material (TIM).

16. The electronic package of claim 15, wherein the lid is attached to the support by a second solder.

17. The electronic package of claim 15, wherein the lid comprises a second shell and a second layer lines the second shell, and wherein an interior volume of the second shell is fluidically coupled to an interior volume of the shell.

18. The electronic package of claim 13, wherein the support is thermally coupled to a thermal block.

19. The electronic package of claim 13, wherein the support comprises a plurality of posts, wherein individual ones of the plurality of posts comprise the shell.

20. The electronic package of claim 13, wherein the die module comprises:
a first die; and
a second die on the first die.

21. The electronic package of claim 13, further comprising:
a component embedded in the package substrate.

22. The electronic package of claim 21, wherein the component is a fully integrated voltage regulator.

23. An electronic system, comprising:
a board;
a package substrate coupled to the board;
a die module coupled to the package substrate; and
a support around a perimeter of the die module, wherein the support comprises a heat pipe or a vapor chamber.

24. The electronic system of claim 23, wherein the support is part of an integrated heat spreader (IHS).

25. The electronic system of claim 23, wherein the support comprises:
a shell; and
a layer over an interior surface of the shell.
